(19) United States
(12) Patent Application Publication
(10) Pub. No.: US 2025/0040346 A1
(43) Pub. Date: Jan. 30, 2025

(54) DISPLAY PANEL AND METHOD FOR MANUFACTURING THE SAME

(71) Applicant: Samsung Display Co., LTD., Yongin-si (KR)

(72) Inventors: KWANHEE LEE, Yongin-si (KR); KIHOON PARK, Yongin-si (KR); KOHEI EBISUNO, Yongin-si (KR); JOONHYOUNG PARK, Yongin-si (KR); SE WAN SON, Yongin-si (KR); SANGHOON OH, Yongin-si (KR); JISEON LEE, Yongin-si (KR); JAESOO JUNG, Yongin-si (KR); HYERI CHO, Yongin-si (KR)

(21) Appl. No.: 18/678,113

(22) Filed: May 30, 2024

(30) Foreign Application Priority Data
Jul. 27, 2023 (KR) 10-2023-0098334

(51) Int. Cl. H10K 59/121; H10K 59/12; H10K 59/122; H10K 59/123; H10K 71/60; H10K 102/10

(52) U.S. Cl. CPC H10K 59/1213; H10K 59/1201; H10K 59/122; H10K 59/123; H10K 71/60; H10K 2102/102; H10K 2102/103

(57) ABSTRACT

A display panel includes a base layer, a circuit element layer, and a light-emitting element layer. The circuit element layer includes a power electrode, and an auxiliary electrode disposed on a side surface of the power electrode. The light-emitting element layer includes a pixel defining film that defines a pixel opening, a conductive partition wall disposed on the pixel defining film, a lower electrode disposed in the pixel opening, a light-emitting pattern disposed on the lower electrode, and an upper electrode disposed on the light-emitting pattern. The conductive partition wall includes a first conductive layer disposed on the pixel defining film, and a second conductive layer, and a side surface of the second conductive layer more protrudes than a side surface of the first conductive layer. The upper electrode is electrically connected to the power electrode via the auxiliary electrode.

This application claims priority to Korean Patent Application No. 10-2023-0098334, filed on Jul. 27, 2023, and all the benefits accruing therefrom under 35 U.S.C. § 119, the content of which in its entirety is herein incorporated by reference.

### BACKGROUND

### 1. Field

Embodiments of the disclosure described herein relate to a display panel and a method for manufacturing the same, and more particularly, to a display panel with improved processability and reliability and a method for manufacturing the same.

### 2. Description of the Related Art

Multimedia electronic devices such as a television, a mobile phone, a tablet, a computer, a navigation, a game console, and the like, are equipped with a display panel for displaying an image.

The display panel includes a light-emitting element and a pixel circuit for operating the light-emitting element. The light-emitting elements included in the display panel emit light and create the image based on a voltage applied from the pixel circuit.

Research is being conducted on a patterning scheme of the light-emitting element to improve reliability of the display panel, and recently, research is being conducted on a scheme for patterning a commonly provided light-emitting material in a pixel unit using an open mask.

### SUMMARY

Embodiments of the disclosure provide a display panel with improved reliability.

Embodiments of the disclosure provide a method for manufacturing a display panel with improved processability and reliability.

In an embodiment of the disclosure, a display panel includes a base layer, a circuit element layer disposed on the base layer, and a light-emitting element layer disposed on the circuit element layer, the circuit element layer includes a power electrode, and an auxiliary electrode disposed on a side surface of the power electrode, the light-emitting element layer includes a pixel defining film that defines a pixel opening, a conductive partition wall disposed on the pixel defining film, a lower electrode disposed in the pixel opening, a light-emitting pattern disposed on the lower electrode, and an upper electrode disposed on the light-emitting pattern, the conductive partition wall includes a first conductive layer disposed on the pixel defining film, and a second conductive layer disposed on the first conductive layer, and a side surface of the second conductive layer more protrudes than a side surface of the first conductive layer, and the upper electrode is electrically connected to the power electrode via the auxiliary electrode.

In an embodiment, the circuit element layer may further include a first circuit layer disposed on the base layer, and a second circuit layer defining an opening and disposed on the first circuit layer, and the power electrode may be disposed in the opening of the second circuit layer.

In an embodiment, the opening of the second circuit layer may be defined to be spaced apart from the lower electrode in a plan view.

In an embodiment, the auxiliary electrode may be disposed directly on the side surface of the power electrode in a plan view.

In an embodiment, the pixel defining film may be disposed on the second circuit layer.

In an embodiment, the auxiliary electrode may include or consist of a same material as that of the lower electrode.

In an embodiment, the auxiliary electrode may be spaced apart from the lower electrode in a plan view and electrically insulated from the lower electrode.

In an embodiment, the circuit element layer may further include a transistor, and the lower electrode may be electrically connected to the transistor.

In an embodiment, the conductive partition wall may further include a third conductive layer disposed between the first conductive layer and the pixel defining film, and a side surface of the third conductive layer may protrude further than the side surface of the second conductive layer.

In an embodiment, the power electrode may include a first layer, a second layer disposed on the first layer, and a third layer disposed on the second layer, and a side surface of the first layer and a side surface of the third layer may protrude further than a side surface of the second layer.

In an embodiment, the lower electrode and the auxiliary electrode may include or consist of ITO.

In an embodiment, the power electrode may include or consist of Al.

In an embodiment of the disclosure, a method for manufacturing a display panel includes preparing a base layer, forming a circuit element layer on the base layer, and forming a light-emitting element layer on the circuit element layer, the forming the circuit element layer includes forming a power electrode on a first circuit layer, and forming a second circuit layer defining an opening that exposes the power electrode on the first circuit layer, the forming the light-emitting element layer includes forming a lower electrode and an auxiliary electrode, forming a pixel defining film that covers a portion of the lower electrode, forming a conductive partition wall on the pixel defining film, forming a light-emitting pattern on the lower electrode, and forming an upper electrode on the light-emitting pattern, the forming the conductive partition wall includes forming a first conductive layer, and forming a second conductive layer on the first conductive layer, and a side surface of the first conductive layer is formed to protrude further than a side surface of the second conductive layer.

In an embodiment, the lower electrode and the auxiliary electrode may include or consist of a same material and may be formed in a same process operation.

In an embodiment, the lower electrode and the auxiliary electrode may be spaced apart from each other in a plan view.

In an embodiment, the auxiliary electrode may be formed at least on a side surface of the power electrode.

In an embodiment, the upper electrode may be formed to overlap the lower electrode and the auxiliary electrode in a plan view.

In an embodiment, the upper electrode may be formed to contact a portion of the auxiliary electrode disposed on a side surface of the power electrode.

In an embodiment, an etch rate of the first conductive layer may be greater than an etch rate of the second conductive layer.

In an embodiment, the forming the conductive partition wall may further include forming a third conductive layer on the second conductive layer, and a side surface of the third conductive layer may be formed to protrude further than the side surface of the second conductive layer.

### BRIEF DESCRIPTION OF THE DRAWINGS

The above and other embodiments, advantages and features of the disclosure will become apparent by describing in detail embodiments thereof with reference to the accompanying drawings.

FIG. 1A is a combined perspective view of an embodiment of a display device according to the disclosure.

FIG. 1B is an exploded perspective view of an embodiment of a display device according to the disclosure.

FIG. 2 is a cross-sectional view of an embodiment of a display module according to the disclosure.

FIG. 3 is a plan view of an embodiment of a display panel according to the disclosure.

FIG. 4 is an enlarged plan view of a portion of a display area of a display panel according to the disclosure.

FIG. 5 is a cross-sectional view of an embodiment of a display panel according to the disclosure.

FIGS. 6A and 6B are cross-sectional views of an embodiment of a display panel according to the disclosure, respectively.

Each of FIGS. 7A to 9 is a cross-sectional view showing an embodiment of one operation of a display panel manufacturing method according to the disclosure.

### DETAILED DESCRIPTION

The disclosure may make various changes and may take various forms, so that illustrative embodiments are to be illustrated in the drawings and described in detail in the text. However, this is not intended to limit the disclosure to a predetermined disclosure form, and should be understood to include all changes, equivalents, or substitutes included in the idea and technical scope of the disclosure.

As used herein, when a component (or a region, a layer, a portion, or the like) is also referred to as being “on”, “connected to”, or “coupled to” another component, it means that the component may be directly disposed/connected/coupled on another component or a third component may be disposed between the component and another component.

In the application, “directly disposed” may mean that there is no layer, film, area, plate, or the like added between one portion of a layer, a film, an area, a plate, or the like and another portion. In an embodiment, “directly disposed” may mean “disposed without using an additional member, such as an adhesive member, between two layers or two members”.

Like reference numerals refer to like components. In addition, in the drawings, thicknesses, ratios, and dimensions of components are exaggerated for effective description of technical content.

“and/of” includes all of one or more combinations that the associated components may define.

Terms such as first, second, or the like may be used to describe various components, but the components should not be limited by the terms. The above terms are used only for the purpose of distinguishing one component from another. For example, without departing from the scope of the present disclosure, a first component may be named as a second component, and similarly, the second component may also be named as the first component. The singular expression includes the plural expression unless the context clearly dictates otherwise.

In addition, terms such as “beneath”, “below”, “on”, “above” are used to describe the relationship of the components shown in the drawings. The above terms are relative concepts, and are described with reference to directions indicated in the drawings. As used herein, “disposed on” may refer to not only a case of being disposed on top of a member, but also a case of being disposed beneath the member.

It should be understood that terms such as “include” or “have” are intended to specify that a feature, a number, a step, an operation, a component, a part, or any combinations thereof described herein is present, and do not preclude a possibility of addition or existence of one or more other features or numbers, steps, operations, components, parts, or combinations thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to the drawings.

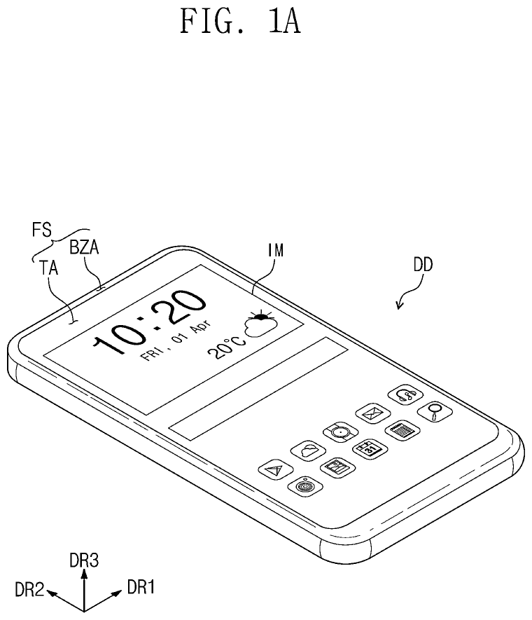

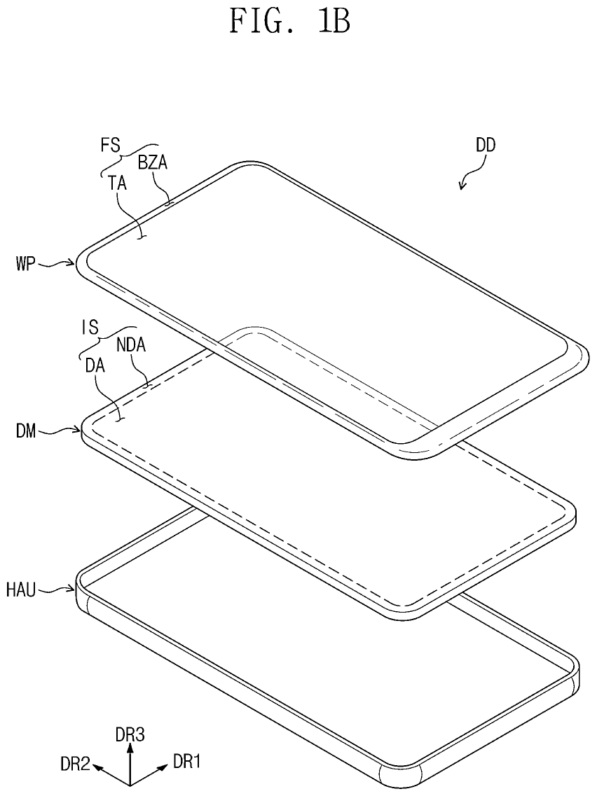

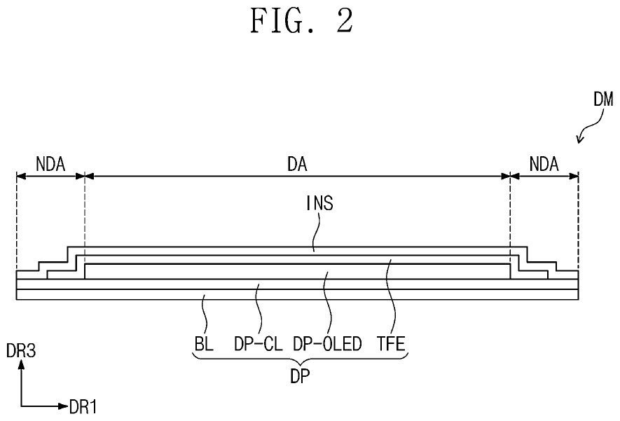

FIG. 1A is a combined perspective view of an embodiment of a display device DD according to the disclosure. FIG. 1B is an exploded perspective view of the display device DD according to the disclosure. FIG. 2 is a cross-sectional view of an embodiment of a display module DM according to the disclosure.

In an embodiment, the display device DD may be a large electronic device such as a television, a monitor, and an external billboard. Additionally, the display device DD may be a small-sized or medium-sized electronic device such as a personal computer, a laptop computer, a personal digital terminal, an automobile navigation unit, a game console, a smartphone, a tablet, and a camera. These are presented merely as examples, and other display devices may be employed as long as they do not deviate from the concept of the disclosure. In the illustrated embodiment, it is shown as an embodiment in which the display device DD is the smartphone.

Referring to FIGS. 1A, 1B, and 2, the display device DD may display an image IM in a third direction DR3 on a display surface FS parallel to each of a first direction DR1 and a second direction DR2. The image IM may include a static image as well as a dynamic image. In FIG. 1A, a clock window and icons are shown in an embodiment of the image IM. The display surface FS on which the image IM is displayed may correspond to a front surface of the display device DD.

In the illustrated embodiment, a front surface (or a top surface) and a rear surface (or a bottom surface) of each member are defined based on the direction in which the image IM is displayed. The front surface and the rear surface may face each other in the third direction DR3, and normal directions of the front surface and the rear surface may be parallel to the third direction DR3. In an embodiment, directions indicated by the first to third directions DR1, DR2, and DR3 are relative concepts and are able to be converted to other directions. As used herein, “in a plan view” may mean “when viewed in the third direction DR3”.

As shown in FIG. 1B, the display device DD in the illustrated embodiment may include a window WP, the display module DM, and a housing HAU. The window WP and the housing HAU may be coupled to each other to form an outer appearance of the display device DD.

The window WP may include or consist of an optically transparent insulating material. In an embodiment, the window WP may include or consist of glass or plastic, for example. A front surface of the window WP may define the display surface FS of the display device DD.

The display surface FS may include a transmissive area TA and a bezel area BZA. The transmissive area TA may be an optically transparent area. In an embodiment, the transmissive area TA may be an area with a visible transmittance equal to or higher than 90%, for example. The bezel area BZA may be an area with a relatively low light transmittance compared to the transmissive area TA. The bezel area BZA may define a shape of the transmissive area TA. The bezel area BZA may be adjacent to the transmissive area TA and may surround the transmissive area TA. This is an exemplary illustration, and in the window WP according to the disclosure, the bezel area BZA may be omitted. The window WP may further include at least one functional layer among an anti-fingerprint layer, a hard coating layer, and an anti-reflection layer, and may not be limited to a particular embodiment.

The display module DM may be disposed beneath the window WP. The display module DM may be a component that actually creates the image IM. The image IM created by the display module DM is displayed on a display surface IS of the display module DM and is visible to a user from the outside via the transmissive area TA.

The display module DM includes a display area DA and a non-display area NDA. The display area DA may be an area activated in response to an electrical signal. The non-display area NDA is adjacent to the display area DA. The non-display area NDA may surround the display area DA. The non-display area NDA is an area covered by the bezel area BZA and is not be visible from the outside.

As shown in FIG. 2, the display module DM in the illustrated embodiment may include a display panel DP and an input sensor INS. Although not separately shown, the display device DD in an embodiment of the disclosure may further include a protection member disposed beneath the display panel DP or an anti-reflection member disposed on top of the input sensor INS.

The display panel DP may be a light-emitting display panel and may not be particularly limited. In an embodiment, the display panel DP may be an organic light-emitting display panel or an inorganic light-emitting display panel, for example. A light-emitting layer in the organic light-emitting display panel includes or consists of an organic light-emitting material. A light-emitting layer in the inorganic light-emitting display panel includes or consists of a quantum dot, a quantum rod, or a micro light-emitting diode (“LED”). Hereinafter, the display panel DP is described as the organic light-emitting display panel.

The display panel DP may include a base layer BL, a circuit element layer DP-CL disposed on the base layer BL, a light-emitting element layer DP-OLED, and a thin film encapsulation layer TFE. The input sensor INS may be disposed directly on the thin film encapsulation layer TFE. As used herein, “a component A is disposed directly on a component B” means that no separate layer, such as an adhesive layer, is disposed between the component A and the component B.

The base layer BL may include at least one plastic film. The base layer BL is a flexible substrate and is able to include a plastic substrate, a glass substrate, a metal substrate, an organic/inorganic composite material substrate, or the like. The display area DA and the non-display area NDA described with reference to FIG. 1B may be defined identically in the base layer BL.

The circuit element layer DP-CL includes at least one insulating layer and a circuit element. The insulating layer includes at least one inorganic layer and at least one organic layer. The circuit element includes signal lines, a driving circuit of a pixel, or the like.

The light-emitting element layer DP-OLED includes a conductive partition wall and a light-emitting element. The light-emitting element includes a lower electrode, a light-emitting pattern, and an upper electrode.

The thin film encapsulation layer TFE includes a plurality of thin films. Some thin films are disposed to improve optical efficiency, and some thin films are disposed to protect organic light-emitting elements.

The input sensor INS acquires coordinate information of an external input. The input sensor INS may have a multi-layer structure. The input sensor INS may include a conductive layer of a single-layer or multi-layer structure. The input sensor INS may include an insulating layer of a single-layer or multi-layer structure. The input sensor INS may sense the external input using, e.g., a capacitance scheme. An operation scheme of the input sensor INS in the disclosure is not particularly limited. In an embodiment of the disclosure, the input sensor INS may sense the external input using an electromagnetic induction scheme or a pressure sensing scheme. In another embodiment of the disclosure, the input sensor INS may be omitted.

As shown in FIG. 1B, the housing HAU may be coupled with the window WP. The housing HAU may be coupled with the window WP to provide a predetermined internal space. The display module DM may be accommodated in the internal space.

The housing HAU may include or consist of a material with relatively high rigidity. In an embodiment, the housing HAU may include a plurality of frames and/or plates including or consisting of glass, plastic, or metal or including or consisting of any combinations thereof, for example. The housing HAU may reliably protect the components of the display device DD accommodated in the internal space from an external impact.

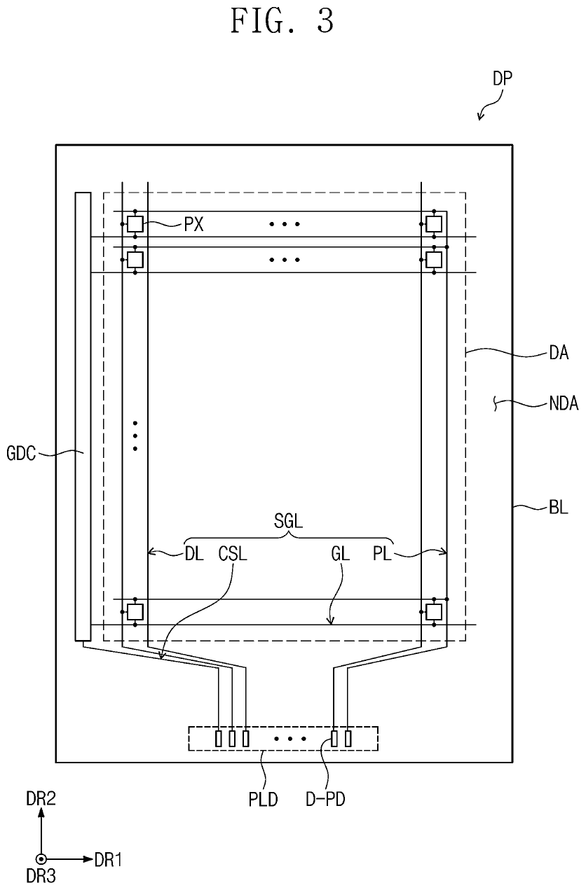

FIG. 3 is a plan view of an embodiment of the display panel DP according to the disclosure.

Referring to FIG. 3, the display panel DP may include the base layer BL divided into the display area DA and the non-display area NDA described with reference to FIG. 2.

The display panel DP may include pixels PX arranged in the display area DA and signal lines SGL electrically connected to the pixels PX. The display panel DP may include a driving circuit GDC and a pad PLD disposed in the non-display area NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, power line PL, and control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to the pixel driving circuit.

The pad PLD may be a portion where a flexible circuit board is connected. The pad PLD may include pixel pads D-PD, and the pixel pads D-PD may be pads for connecting the flexible circuit board to the display panel DP. Each of the pixel pads D-PD may be connected to a corresponding signal line among the signal lines SGL. The pixel pads D-PD may be connected to the corresponding pixels PX via the signal lines SGL. Additionally, one of the pixel pads D-PD may be connected to the driving circuit GDC.

Additionally, the pad PLD may further include input pads. The input pads may be pads for connecting the flexible circuit board to the input sensor INS (refer to FIG. 2). However, the disclosure may not be limited thereto, and the input pads may be disposed on the input sensor INS (refer to FIG. 2) and connected to the pixel pads D-PD and a separate circuit board. In an alternative embodiment, the input sensor INS (refer to FIG. 2) may be omitted and no further input pads may be included.

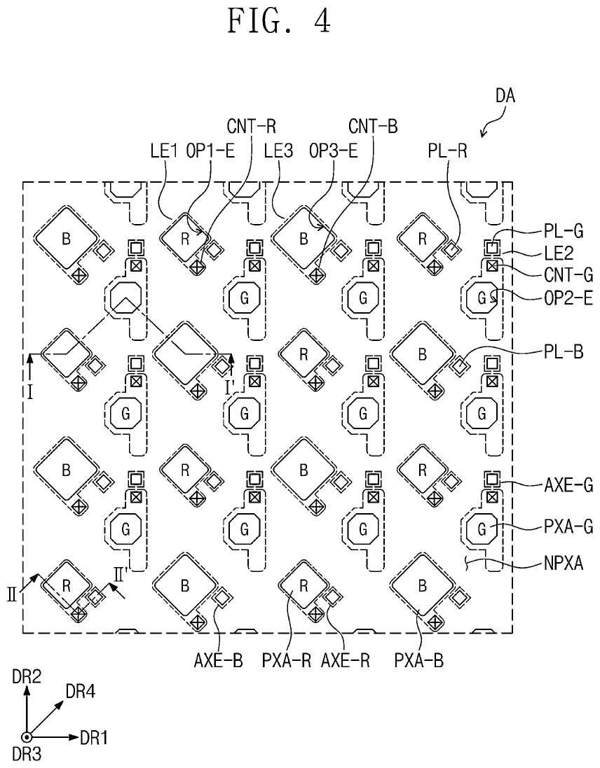

FIG. 4 is an enlarged plan view of an embodiment of a portion of the display area DA of the display panel according to the disclosure.

FIG. 4 is an enlarged view of a portion of the display area DA in a plane of the display module DM (refer to FIG. 1B) viewed from the display surface IS (refer to FIG. 1B) of the display module DM (refer to FIG. 1B), and shows arrangement of light-emitting areas PXA-R, PXA-G, and PXA-B.

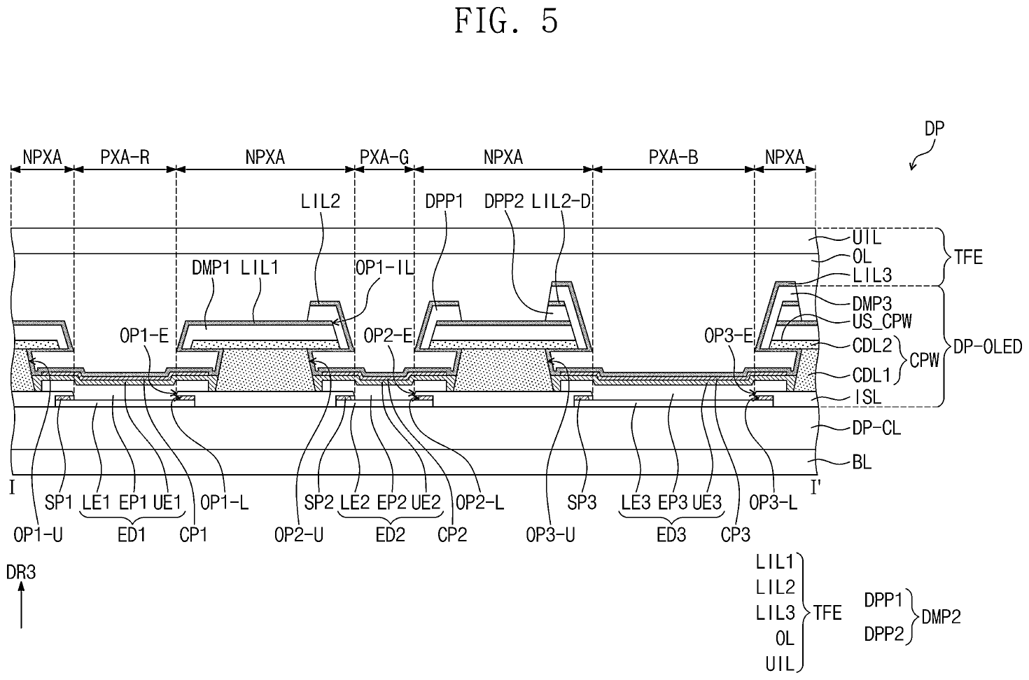

Referring to FIG. 4, the display area DA may include the first to third light-emitting areas PXA-R, PXA-G, and PXA-B and a non-light-emitting area NPXA surrounding the first to third light-emitting areas PXA-R, PXA-G, and PXA-B. The first to third light-emitting areas PXA-R, PXA-G, and PXA-B may correspond to areas where light provided from light-emitting elements ED1, ED2, and ED3 (refer to FIG. 5) is emitted, respectively. In FIG. 4, for convenience of description, only lower electrodes LE1, LE2, and LE3 among components of the light-emitting elements ED1, ED2, and ED3 (refer to FIG. 5) are shown in an embodiment. The first to third light-emitting areas PXA-R, PXA-G, and PXA-B may be distinguished from each other based on a color of light emitted toward the outside of the display module DM (refer to FIG. 1B).

The first to third light-emitting areas PXA-R, PXA-G, and PXA-B may provide first to third color light having different colors, respectively. In an embodiment, the first color light may be red light, the second color light may be green light, and the third color light may be blue light, for example. However, embodiments of the first to third color light are not necessarily limited to the above examples.

The non-light-emitting area NPXA may set boundaries of the first to third light-emitting areas PXA-R, PXA-G, and PXA-B, and may prevent color mixing between the first to third light-emitting areas PXA-R, PXA-G, and PXA-B.

The first to third light-emitting areas PXA-R, PXA-G, and PXA-B may respectively include a plurality of first light-emitting areas, a plurality of second light-emitting areas, and a plurality of third light-emitting areas that are repeatedly arranged with predetermined arrangement within the display area DA. In an embodiment, the first and third light-emitting areas PXA-R and PXA-B may be arranged alternately along the first direction DR1 to form a ‘first group’, for example. The second light-emitting areas PXA-G may be arranged along the first direction DR1 to form a ‘second group’. The ‘first group’ and the ‘second group’ may respectively include a plurality of first groups and a plurality of second groups, and the ‘first groups’ and the ‘second groups’ may be arranged alternately with each other along the second direction DR2.

The one second light-emitting area PXA-G may be spaced apart from the one first light-emitting area PXA-R or the one third light-emitting area PXA-B in a fourth direction DR4. The fourth direction DR4 may be defined as a direction between the first and second directions DR1 and DR2.

FIG. 4 shows the arrangement of the first to third light-emitting areas PXA-R, PXA-G, and PXA-B in an embodiment, and the first to third light-emitting areas PXA-R, PXA-G, and PXA-B may be arranged in various forms without being limited thereto. In an embodiment, the first to third light-emitting areas PXA-R, PXA-G, and PXA-B may have a PENTILE™ arrangement form as shown in FIG. 4. In an alternative embodiment, the first to third light-emitting areas PXA-R, PXA-G, and PXA-B may have a stripe arrangement form or a diamond Pixel™ arrangement form.

The first to third light-emitting areas PXA-R, PXA-G, and PXA-B may have various shapes in a plan view. In an embodiment, the first to third light-emitting areas PXA-R, PXA-G, and PXA-B may have shapes such as a polygon, a circle, or an ellipse. FIG. 4 shows the first and third light-emitting areas PXA-R and PXA-B having a square shape (or a diamond shape) and the second light-emitting area PXA-G having an octagonal shape in a plan view in an embodiment, for example.

The first to third light-emitting areas PXA-R, PXA-G, and PXA-B may have the same shape as each other in the plan view, or at least some of them may have different shapes. FIG. 4 shows the first and third light-emitting areas PXA-R and PXA-B having the same shape as each other in the plan view and the second light-emitting area PXA-G having a shape different from that of the first and third light-emitting areas PXA-R and PXA-B in an embodiment.

At least some of the first to third light-emitting areas PXA-R, PXA-G, and PXA-B may have different area sizes in the plan view. In an embodiment, an area size of the first light-emitting area PXA-R that emits red light may be larger than an area size of the second light-emitting area PXA-G that emits green light, and may be smaller than an area size of the third light-emitting area PXA-B that emits blue light. However, a size relationship between the area sizes of the first to third light-emitting areas PXA-R, PXA-G, and PXA-B based on the emitted light color may not be limited thereto, and may be diverse depending on a design of the display module DM (refer to FIG. 2). Additionally, without being limited thereto, the first to third light-emitting areas PXA-R, PXA-G, and PXA-B may have the same area size in the plan view.

In an embodiment, the shapes, the area sizes, the arrangement, or the like of the first to third light-emitting areas PXA-R, PXA-G, and PXA-B in the display module DM (refer to FIG. 1B) according to the disclosure may be designed in various ways depending on a size and components of the display module DM (refer to FIG. 1B), and may not be limited to those in the embodiment shown in FIG. 4.

The lower electrodes LE1, LE2, and LE3 may be connected to the driving circuits of the pixels in the circuit element layer DP-CL (refer to FIG. 2) described above via connection contact holes CNT-R, CNT-G, and CNT-B. The connection contact holes CNT-R, CNT-G, and CNT-B may include the first connection contact hole CNT-R, the second connection contact hole CNT-G, and the third connection contact hole CNT-B. The first connection contact hole CNT-R may be defined as an area where the first lower electrode LE1 is connected to a driving circuit of a corresponding pixel, the second connection contact hole CNT-G may be defined as an area where the second lower electrode LE2 is connected to a driving circuit of a corresponding pixel, and the third connection contact hole CNT-B may be defined as an area where the third lower electrode LE3 is connected to a driving circuit of a corresponding pixel.

The connection contact holes CNT-R, CNT-G, and CNT-B may be spaced apart from the light-emitting areas PXA-R, PXA-G, and PXA-B defined in the lower electrodes LE1, LE2, and LE3, respectively. However, this is merely one of embodiments, and the connection contact holes CNT-R, CNT-G, and CNT-B may be disposed to overlap the light-emitting areas PXA-R, PXA-G, and PXA-B defined in the lower electrodes LE1, LE2, and LE3, respectively.

FIG. 4 shows auxiliary electrodes AXE-R, AXE-G, and AXE-B and power electrodes PL-R, PL-G, and PL-B disposed in the non-light-emitting area NPXA.

The auxiliary electrodes AXE-R, AXE-G, and AXE-B may include or consist of the same material as that of the lower electrodes LE1, LE2, and LE3. The auxiliary electrodes AXE-R, AXE-G, and AXE-B may be formed via the same process operation as the lower electrodes LE1, LE2, and LE3. The auxiliary electrodes AXE-R, AXE-G, and AXE-B may be electrically insulated from the lower electrodes LE1, LE2, and LE3 by being disposed to be spaced apart therefrom in the plan view.

Upper electrodes UE1, UE2, and UE3 (refer to FIG. 5) are electrically connected to the power electrodes PL-R, PL-G, and PL-B with the auxiliary electrodes AXE-R, AXE-G, and AXE-B interposed therebetween, respectively, and a detailed description thereof will be provided later.

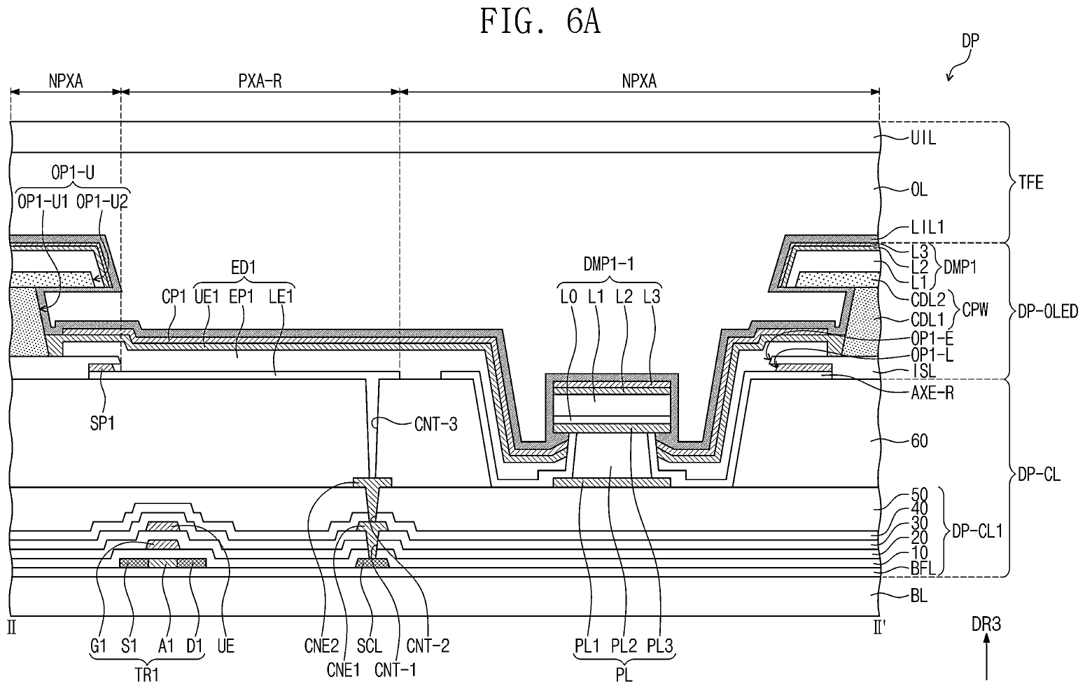

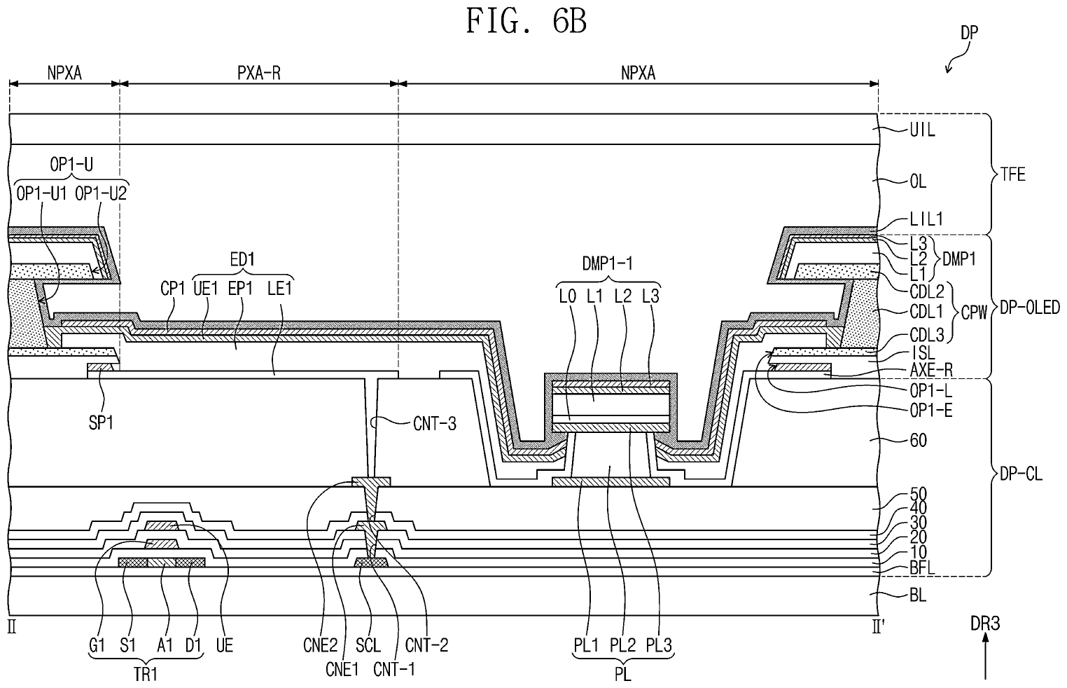

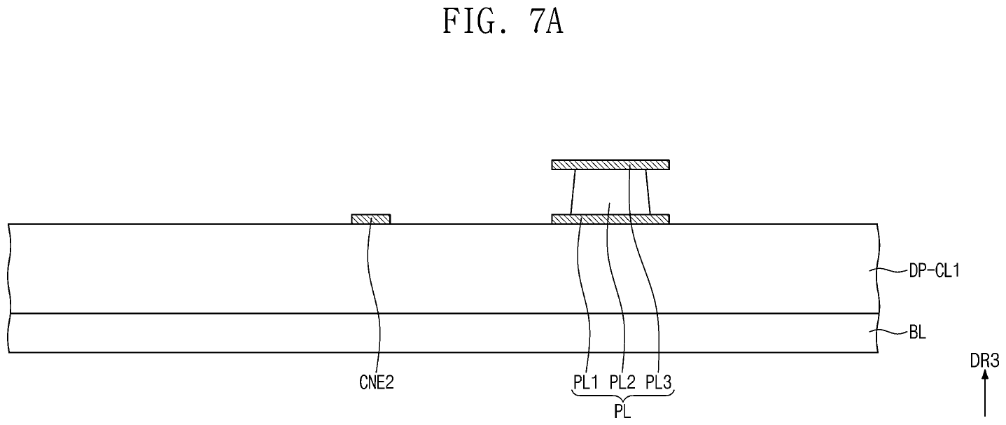

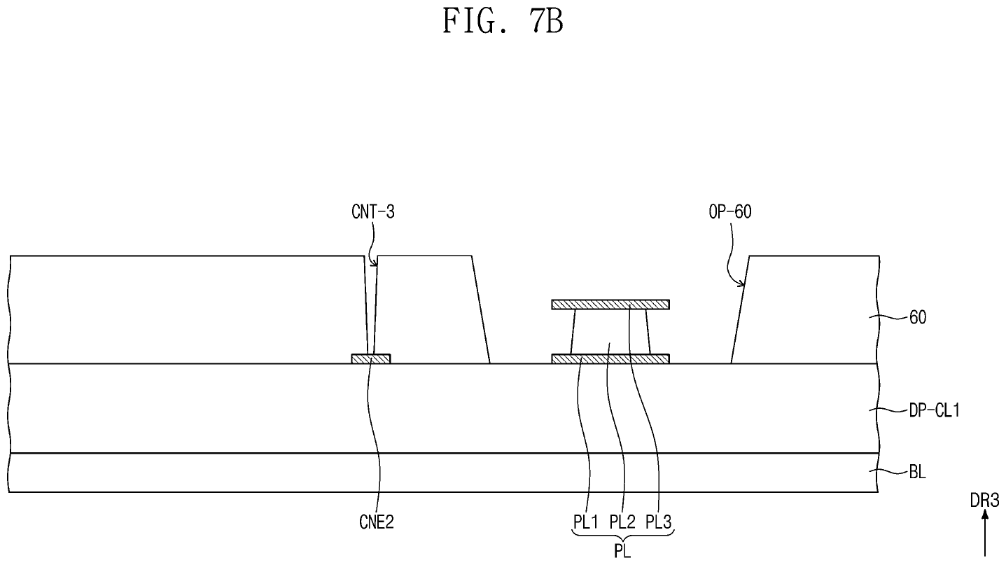

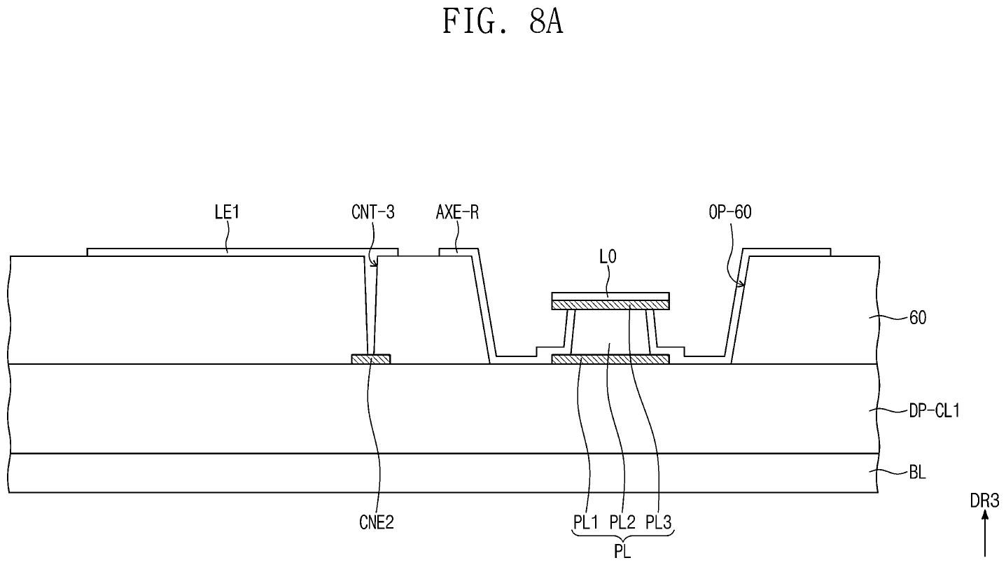

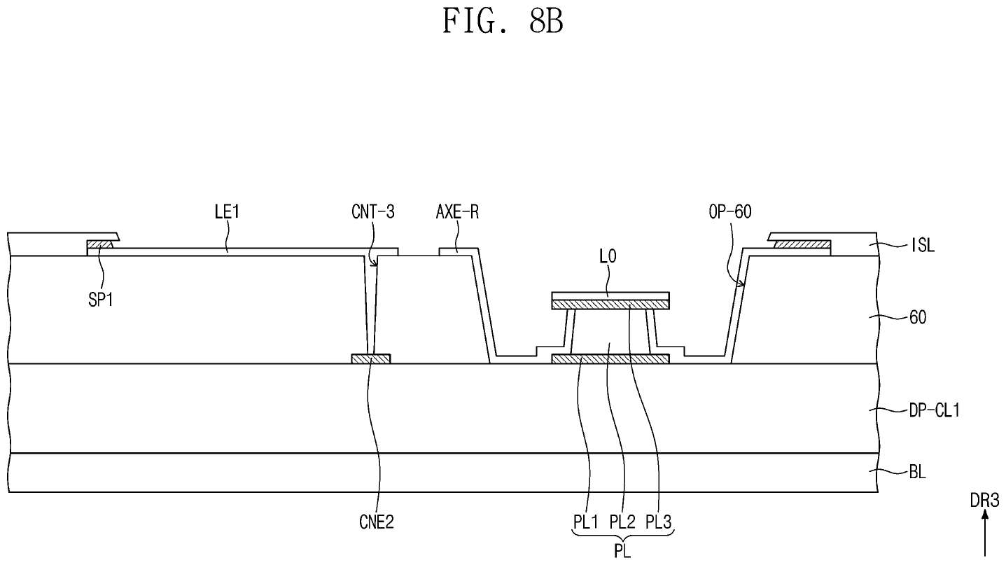

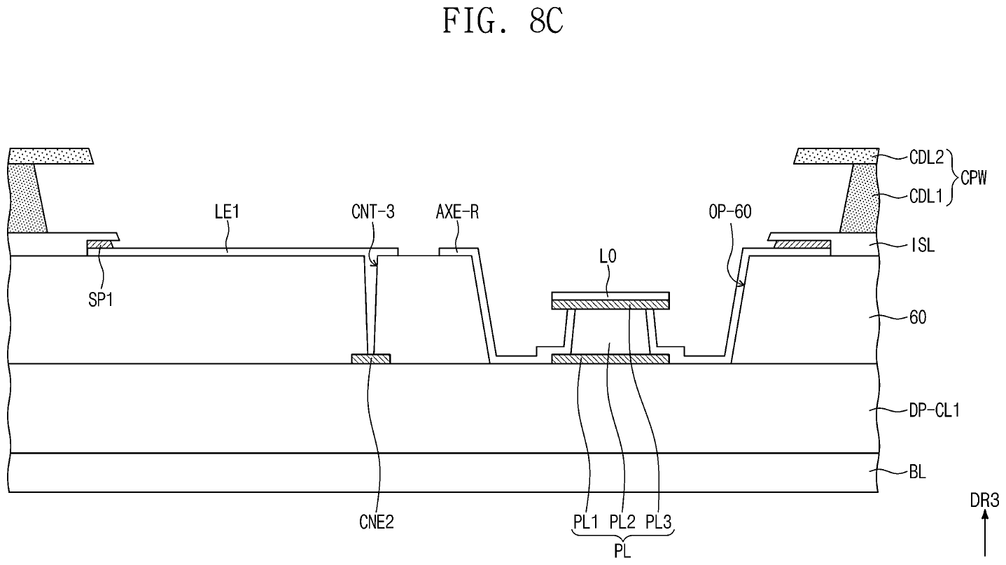

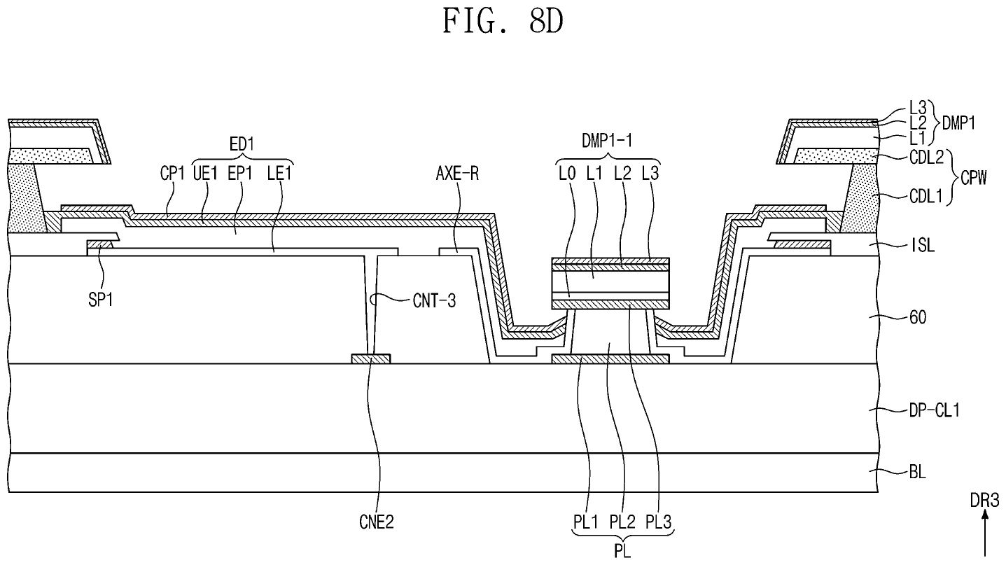

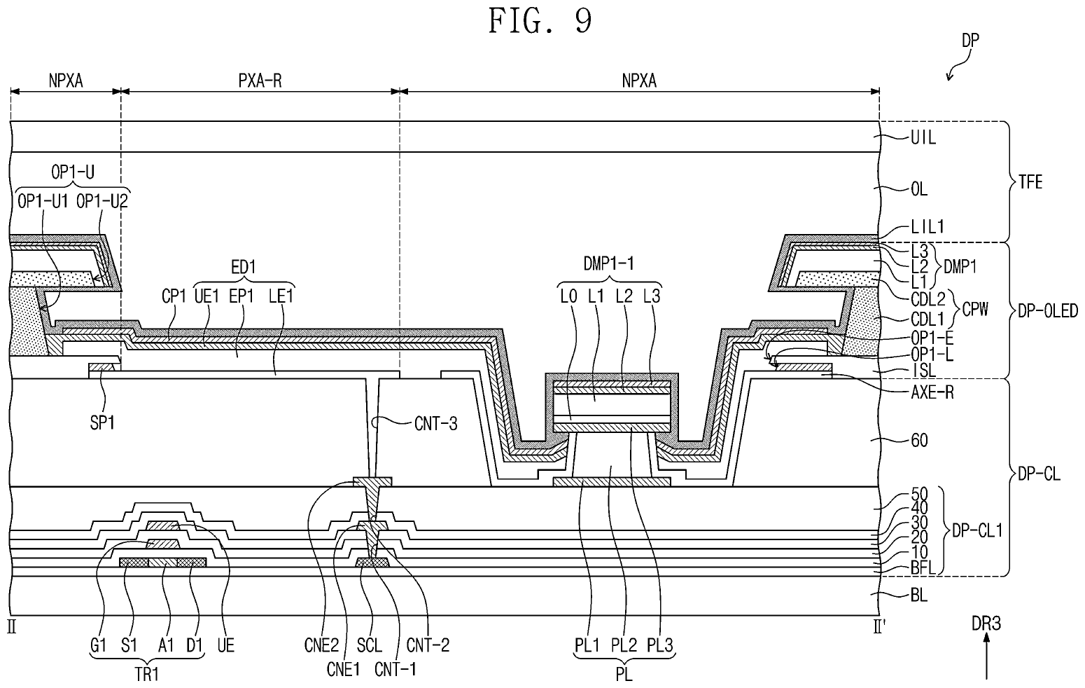

FIG. 5 is a cross-sectional view of an embodiment of the display panel DP according to the disclosure. FIGS. 6A and 6B are cross-sectional views of an embodiment of the display panel DP according to the disclosure, respectively.

FIG. 5 shows a cross-section taken along line I-I′ in FIG. 4. FIGS. 6A and 6B show cross-sections taken along line II-II′ in FIG. 4, respectively.

Referring to FIGS. 5 to 6B, the display panel DP may include the base layer BL, the circuit element layer DP-CL, the light-emitting element layer DP-OLED, and the thin film encapsulation layer TFE.

The base layer BL may include a synthetic resin film. In addition, the base layer BL may include a glass substrate, a metal substrate, or an organic/inorganic composite material substrate.

Referring to FIG. 6A, at least one inorganic layer is disposed on a top surface of the base layer BL. A buffer layer BFL improves a bonding strength between the base layer BL and a semiconductor pattern. The buffer layer BFL may include a silicon oxide layer and a silicon nitride layer. The silicon oxide layers and the silicon nitride layers may be alternately stacked.

The display panel DP may include a plurality of insulating layers, the semiconductor pattern, a conductive pattern, a signal line, or the like. The insulating layer, a semiconductor layer, and a conductive layer are formed via schemes such as coating, deposition, or the like. Thereafter, the insulating layer, the semiconductor layer, and the conductive layer may be selectively patterned by photolithography and etching. With such scheme, the semiconductor pattern, the conductive pattern, the signal line, or the like included in the circuit element layer DP-CL and the light-emitting element layer DP-OLED are formed.

The semiconductor pattern is disposed on the buffer layer BFL. The semiconductor pattern may include or consist of polysilicon. However, without being limited thereto, the semiconductor pattern may include or consist of amorphous silicon or metal oxide.

FIG. 6A only shows a partial semiconductor pattern, and the semiconductor pattern may be further disposed in the plurality of light-emitting areas PXA-R, PXA-G, and PXA-B. The semiconductor pattern may be arranged in a predetermined order across the plurality of light-emitting areas PXA-R, PXA-G, and PXA-B. The semiconductor pattern has different electrical properties depending on whether it is doped. The semiconductor pattern may include a first area with a relatively high doping concentration and a second area with a relatively low doping concentration. The first area may be doped with an N-type dopant or a P-type dopant. A P-type transistor includes the first area doped with the P-type dopant.

The first area has greater conductivity than the second area and substantially functions as an electrode or a signal line. The second area substantially corresponds to an active (or a channel) of the transistor. In other words, a portion of the semiconductor pattern may be the active of the transistor, another portion thereof may be a source or a drain of the transistor, and another portion thereof may be a conductive area.

As shown in FIG. 6A, a source Si, an active A1, and a drain D1 of a transistor TR1 are formed from the semiconductor pattern. FIG. 6A shows a portion of a signal transfer area SCL formed from the semiconductor pattern. Although not separately shown, the signal transfer area SCL may be connected to the drain D1 of the transistor TR1 in a plan view.

First to sixth insulating layers 10 to 60 are disposed on the buffer layer BFL. The first to sixth insulating layers 10 to 60 may be an inorganic layer or an organic layer. A gate G1 is disposed on the first insulating layer 10. An upper electrode UE may be disposed on the second insulating layer 20. A first connection electrode CNE1 may be disposed on the third insulating layer 30. The first connection electrode CNE1 may be connected to the signal transfer area SCL via a contact hole CNT-1 extending through the first to third insulating layers 10 to 30. The fourth insulating layer 40 may be disposed on the third insulating layer 30 and cover the first connection electrode CNE1. The fifth and sixth insulating layers 50 and 60 may be disposed on the fourth insulating layer 40. In an embodiment, the fifth and sixth insulating layers 50 and 60 may be the organic layers. The buffer layer BFL and the first to fifth insulating layers 10, 20, 30, 40, and 50 may be also referred to as a first circuit layer DP-CL1 and the sixth insulating layer 60 may be also referred to as the second circuit layer 60 in a description of a manufacturing method of FIGS. 7A to 9 to be made later.

A second connection electrode CNE2 may be disposed on the fifth insulating layer 50. The second connection electrode CNE2 may be connected to the first connection electrode CNE1 via a contact hole CNT-2 extending through the fourth and fifth insulating layers 40 and 50.

Referring to FIG. 6A, the power electrode PL and the auxiliary electrode AXE-R may be disposed on the fifth insulating layer 50 of the non-light-emitting area NPXA adjacent to the first light-emitting area PXA-R.

A bias voltage may be applied to the power electrode PL. The power electrode PL may have a single-layer or multi-layer structure. In an embodiment, the power electrode PL may include a first layer PL1, a second layer PL2, and a third layer PL3, for example. In an embodiment, the first layer PL1, the second layer PL2, and the third layer PL3 may be ITO, Ag, and ITO, respectively, for example. Side surfaces of the first layer PL1 and the third layer PL3 may protrude more than a side surface of the second layer PL2. The side surface of the third layer PL3 may protrude more than the side surface of the second layer PL2 to form a tip. In FIG. 6A, the power electrode PL is shown as having a three-layer structure and forming the tip, but a stacked structure and a shape of the power electrode PL are not limited thereto.

The auxiliary electrode AXE-R may be formed via the same process as and may include or consist of the same material as that of the lower electrode LE1 to be described later. The auxiliary electrode AXE-R may be disposed on a side surface of the power electrode PL.

The upper electrode UE1, which will be described later, may extend from the first light-emitting area PXA-R and be electrically connected to the power electrode PL. Specifically, the upper electrode UE1 may be electrically connected to the power electrode PL with the auxiliary electrode AXE-R interposed therebetween. The upper electrode UE1 may be disposed in contact with the auxiliary electrode AXE-R disposed on the side surface of the power electrode PL. Accordingly, the upper electrode UE1 may receive the bias voltage applied to the power electrode PL.

As the upper electrode UE1 is connected to the power electrode PL with the auxiliary electrode AXE-R interposed therebetween, electrical contact stability is improved, improving brightness of the display panel DP and reducing defects.

In addition, a process, which is for the connection of the upper electrode UE1 and the power electrode PL, of bringing the upper electrode UE1 into contact with a side surface of a conductive partition wall CPW and defining a separate contact hole to connect the upper electrode UE1 to the power electrode PL may be omitted, thereby simplifying the process.

A dummy DMP1-1 may be disposed on the power electrode PL. The dummy DMP1-1 may include a first dummy L0 formed together with and including or consisting of the same material as that of the lower electrode LE1 and the auxiliary electrode AXE 1, a second dummy L1 formed together with and including or consisting of the same material as a light-emitting pattern EP1, a third dummy L2 formed together with and including or consisting of the same material as that of the upper electrode UE1, and a fourth dummy L3 formed together with and including or consisting of the same material as a capping pattern CP1.

The power electrode PL and the dummy DMP1-1 may be covered by an inorganic layer LIL1 of the encapsulation layer TFE.

The light-emitting element layer DP-OLED may be disposed on the circuit element layer DP-CL. In the illustrated embodiment, the light-emitting element layer DP-OLED may include the light-emitting elements ED1, ED2, and ED3, sacrificial patterns SP1, SP2, and SP3, an insulating film ISL, the conductive partition wall CPW, dummy patterns DMP1, DMP2, and DMP3, and a dummy inorganic layer LIL2-D.

The light-emitting elements ED1, ED2, and ED3 include the first light-emitting element ED1, the second light-emitting element ED2, and the third light-emitting element ED3. The first light-emitting element ED1 may include the first lower electrode LE1, the first light-emitting pattern EP1, and the first upper electrode UE1, the second light-emitting element ED2 may include the second lower electrode LE2, a second light-emitting pattern EP2, and the second upper electrode UE2, and the third light-emitting element ED3 may include the third lower electrode LE3, a third light-emitting pattern EP3, and the third upper electrode UE3. The light-emitting patterns EP1, EP2, and EP3 may be also referred to as the light-emitting layer.

The first to third lower electrodes LE1, LE2, and LE3 may be provided as a plurality of patterns. Hereinafter, a description will focus on the first lower electrode LE1, and the description of the first lower electrode LE1 may be equally applied to the second and third lower electrodes LE2 and LE3.

The first lower electrode LE1 may be disposed on the sixth insulating layer 60 of the circuit element layer DP-CL. The first lower electrode LE1 may be connected to the second connection electrode CNE2 via a connection contact hole CNT-3 defined through the sixth insulating layer 60. Accordingly, the first lower electrode LE1 may be electrically connected to the signal transfer area SCL via the first and second connection electrodes CNE1 and CNE2 and be electrically connected to a corresponding circuit element. The connection contact hole CNT-3 in FIG. 6A may correspond to the first connection contact hole CNT-R in FIG. 4.

The first lower electrode LE1 may be a (semi-)transparent electrode or a reflective electrode. In the illustrated embodiment, the first lower electrode LE1 may include a multi-layer structure. In an embodiment, the first lower electrode LE1 may include a first layer, a second layer disposed on the first layer, and a third layer disposed on the second layer, for example.

The second layer may include or consist of a metallic material. In an embodiment, the second layer may be a reflective layer including or consisting of silver (Ag), magnesium (Mg), aluminum (Al), platinum (Pt), palladium (Pd), gold (Au), nickel (Ni), neodymium (Nd), iridium (Ir), chromium (Cr), or any combinations thereof, for example.

Each of the first layer and the third layer may include or consist of a transparent conductive oxide. In an embodiment, each of the first layer and the third layer may be a transparent or translucent electrode layer including or consisting of at least one selected from a group including indium tin oxide (“ITO”), indium zinc oxide (“IZO”), indium gallium zinc oxide (“IGZO”), zinc oxide (ZnO), indium oxide (In₂O₃), and aluminum-doped zinc oxide (“AZO”), for example.

The sacrificial patterns SP1, SP2, and SP3 may include the first sacrificial pattern SP1 disposed on a top surface of the first lower electrode LE1, the second sacrificial pattern SP2 disposed on a top surface of the second lower electrode LE2, and the third sacrificial pattern SP3 disposed on a top surface of the third lower electrode LE3.

A first lower opening OP1-L that exposes a portion of the top surface of the first lower electrode LE1 may be defined in the first sacrificial pattern SP1, a second lower opening OP2-L that exposes a portion of the top surface of the second sacrificial pattern SP2 may be defined in the second sacrificial pattern SP2, and a third lower opening OP3-L that exposes a portion of the top surface of the third lower electrode LE3 may be defined in the third sacrificial pattern SP3.

In the illustrated embodiment, each of the first to third sacrificial patterns SP1, SP2, and SP3 may include or consist of an amorphous transparent conductive oxide. According to the disclosure, during an etching process of the first sacrificial pattern SP1 to define the first lower opening OP1-L therein, the first lower electrode LE1 may be prevented from being etched together and damaged, and a description thereof may also be equally applied to the second sacrificial pattern SP2 and the third sacrificial pattern SP3.

The insulating film ISL may be disposed on the sixth insulating layer 60 of the circuit element layer DP-CL. The insulating film ISL may cover the first to third lower electrodes LE1, LE2, and LE3 and the first to third sacrificial patterns SP1, SP2, and SP3. That is, the insulating film ISL may cover a top surface of each of the first to third sacrificial patterns SP1, SP2, and SP3. Herein, the insulating film ISL may be also referred to as a pixel defining film, a pixel defining layer or an insulating layer.

As shown in FIG. 5, first to third light-emitting openings OP1-E, OP2-E, and OP3-E may be defined in the insulating film ISL. The first light-emitting opening OP1-E may correspond to the first lower opening OP1-L of the first sacrificial pattern SP1, the second light-emitting opening OP2-E may correspond to the second lower opening OP2-L of the second sacrificial pattern SP2, and the third light-emitting opening OP3-E may correspond to the third lower opening OP3-L of the third sacrificial pattern SP3.

The first to third light-emitting openings OP1-E, OP2-E, and OP3-E may be also referred to as pixel openings. The pixel opening may refer to an area exposed by the pixel defining layer ISL. Referring to FIG. 6B, the pixel opening may include the first light-emitting area PXA-R and may include a portion of the non-light-emitting area NPXA where the power electrode PL is disposed.

In the illustrated embodiment, in a plan view, the first light-emitting opening OP1-E may overlap the first lower opening OP1-L, and an area size of the first light-emitting opening OP1-E may be smaller than an area size of the first lower opening OP1-L. In other words, an inner surface of the insulating film ISL, which defines the first light-emitting opening OP1-E therein, may be closer to a center of the first lower electrode LE1 than an inner surface of the first sacrificial pattern SP1 is to the first lower electrode LE1, which defines the first lower opening OP1-L therein. In this regard, a portion of the insulating film ISL more adjacent to the center of the first lower electrode LE1 than the inner surface of the first sacrificial pattern SP1 defining the first lower opening OP1-L therein may define a tip. The description of the first light-emitting opening OP1-E and the first lower opening OP1-L may be equally applied to the second light-emitting opening OP2-E and the second lower opening OP2-L, and the third light-emitting opening OP3-E and the third lower opening OP3-L.

The insulating film ISL may include or consist of an inorganic insulating material, e.g., silicon nitride (SiNₓ). The insulating film ISL may be disposed between the first to third lower electrodes LE1, LE2, and LE3 and the conductive partition wall CPW, and block the first to third lower electrodes LE1, LE2, and LE3 and the conductive partition wall CPW from being electrically connected to each other.

The conductive partition wall CPW may be disposed on the insulating film ISL. First to third upper openings OP1-U, OP2-U, and OP3-U may be defined in the conductive partition wall CPW. The first upper opening OP1-U may correspond to the first light-emitting opening OP1-E, the second upper opening OP2-U may correspond to the second light-emitting opening OP2-E, and the third upper opening OP3-U may correspond to the third light-emitting opening OP3-E.

In the illustrated embodiment, the conductive partition wall CPW may include a first conductive layer CDL1 and a second conductive layer CDL2. Each of the first conductive layer CDL1 and the second conductive layer CDL2 may include or consist of a conductive material. The first conductive layer CDL1 may be disposed on the insulating film ISL and may have first conductivity and a first thickness. The second conductive layer CDL2 may be disposed on the first conductive layer CDL1, have second conductivity lower than the first conductivity, and have a second thickness smaller than the first thickness.

An etch rate of the first conductive layer CDL1 may be greater than an etch rate of the second conductive layer CDL2. That is, the first conductive layer CDL1 may include or consist of a material with higher etch selectivity than that of the second conductive layer CDL2.

In an embodiment, each of the first and second conductive layers CDL1 and CDL2 may include or consist of a metal material. Additionally, in an embodiment, the second conductive layer CDL2 may include or consist of a material having a lower reflectance than the first conductive layer CDL1, and may substantially reduce reflectance at a top surface of the second conductive layer CDL2, which forms a top surface US_CPW of the conductive partition wall CPW, thereby improving a display quality of the display panel DP. In an embodiment, the first conductive layer CDL1 may include or consist of aluminum (Al), and the second conductive layer CDL2 may include or consist of titanium (Ti), for example. However, the materials of the first and second conductive layers CDL1 and CDL2 are not limited to a particular embodiment.

In the illustrated embodiment, in a plan view, the first upper opening OP1-U defined in the second conductive layer CDL2 may overlap the first upper opening OP1-U defined in the first conductive layer CDL1, and an area of the first upper opening OP1-U defined in the second conductive layer CDL2 may be smaller than an area of the first upper opening OP1-U defined in the first conductive layer CDL1.

As shown in FIG. 6A, in a cross-section, the first upper opening OP1-U may include a first area OP1-U1 defined by an inner surface of the first conductive layer CDL1 and a second area OP1-U2 defined by an inner surface of the second conductive layer CDL2. In the cross-section, a width of the first area OP1-U1 may be greater than a width of the second area OP1-U2. In the cross-section, the inner surface of the second conductive layer CDL2, which defines the second area OP1-U2, may be closer to the center of the first lower electrode LE1 than the inner surface of the first conductive layer CDL1, which defines the first area OP1-U1, is to the center of the first lower electrode LE1. In the disclosure, in the conductive partition wall CPW, a portion of the second conductive layer CDL2 more adjacent to the center of the first lower electrode LE1 than the inner surface of the first conductive layer CDL1 defining the first area OP1-U1 may be defined as a tip.

In an embodiment, in a plan view, an area size of the first upper opening OP1-U1 defined in the first conductive layer CDL1 may be larger than the area size of the first light-emitting opening OP1-E defined in the insulating film ISL, and the first conductive layer CDL1 may expose a portion of a top surface of the insulating film ISL by the first upper opening OP1-U1.

Each of the first to third light-emitting patterns EP1, EP2, and EP3 may be disposed on a corresponding lower electrode among the first to third lower electrodes LE1, LE2, and LE3. The first light-emitting pattern EP1 may be disposed on the first upper electrode UE1, the second light-emitting pattern EP2 may be disposed on the second upper electrode UE2, and the third light-emitting pattern EP3 may be disposed on the third upper electrode UE3. In an embodiment, the first light-emitting pattern EP1 may provide red light, the second light-emitting pattern EP2 may provide green light, and the third light-emitting pattern EP3 may provide blue light.

Each of the first to third light-emitting patterns EP1, EP2, and EP3 may include a light-emitting layer including or consisting of a light-emitting material. Each of the first to third light-emitting patterns EP1, EP2, and EP3 may further include a hole injection layer (“HIL”) and a hole transport layer (“HTL”) disposed between the light-emitting layer and the corresponding lower electrode among the first to third lower electrodes LE1, LE2, and LE3, and may further include an electron transport layer (“ETL”) and an electron injection layer (“EIL”) disposed on the light-emitting layer. Each of the first to third light-emitting patterns EP1, EP2, and EP3 may be also referred to as an ‘organic pattern’.

According to the disclosure, the first to third light-emitting patterns EP1, EP2, and EP3 may be patterned by the tip defined in the conductive partition wall CPW. The first light-emitting pattern EP1 may be disposed inside the first lower opening OP1-L, the first light-emitting opening OP1-E, and the first upper opening OP1-U. The first light-emitting pattern EP1 may cover a portion of the top surface of the insulating film ISL exposed by the first upper opening OP1-U. The second light-emitting pattern EP2 may be disposed inside the second lower opening OP2-L, the second light-emitting opening OP2-E, and the second upper opening OP2-U. The second light-emitting pattern EP2 may cover a portion of the top surface of the insulating film ISL exposed by the second upper opening OP2-U. The third light-emitting pattern EP3 may be disposed inside the third lower opening OP3-L, the third light-emitting opening OP3-E, and the third upper opening OP3-U. The third light-emitting pattern EP3 may cover a portion of the top surface of the insulating film ISL exposed by the third upper opening OP3-U.

According to the disclosure, the plurality of first light-emitting patterns EP1 may be patterned in a pixel unit and deposited by the tip defined in the conductive partition wall CPW. That is, the plurality of first light-emitting patterns EP1 may be commonly formed using an open mask, but may be easily divided from each other in the pixel unit by the conductive partition wall CPW.

When patterning the plurality of first light-emitting patterns EP1 using a separate mask (e.g., a fine metal mask (FMM)), a spacer for support that protrudes from the partition wall should be provided to support the separate mask. Additionally, as the separate mask is spaced apart from a base surface where the patterning is performed by a height of the partition wall and the spacer, there may be a limit to improvement in resolution.

Additionally, as the mask contacts the spacer, foreign substances may remain on the spacer after the patterning process of the plurality of first light-emitting patterns EP1, and the spacer damaged by scratch of the mask may be provided. Accordingly, a defective display panel may be formed.

In the disclosure, as the plurality of first light-emitting patterns EP1 are patterned without the separate mask that contacts the internal components of the display panel DP, the display panel DP with improved reliability resulted from a reduced defect rate may be provided. In particular, when manufacturing the large-area display panel DP, a process cost may be reduced by omitting manufacturing of a large-area mask, and the display panel DP that is not affected by defects that occur in the large-area mask, and thus, has the improved reliability may be provided.

It is shown in FIG. 6A as an embodiment in which the first light-emitting pattern EP1 is not in contact with the inner surface of the first conductive layer CDL1 that defines the first upper opening OP1-U1 therein, but the disclosure is not limited thereto. In an embodiment, the first light-emitting pattern EP1 may contact the inner surface of the first conductive layer CDL1 that defines the first upper opening OP1-U therein, for example.

The description of the first light-emitting pattern EP1 above may be equally applied to the second and third light-emitting patterns EP2 and EP3.

Each of the first to third upper electrodes UE1, UE2, and UE3 may be disposed on a corresponding light-emitting pattern among the first to third light-emitting patterns EP1, EP2, and EP3. The first upper electrode UE1 may be disposed on the first light-emitting pattern EP1, the second upper electrode UE2 may be disposed on the second light-emitting pattern EP2, and the third upper electrode UE3 may be disposed on the third light-emitting pattern EP3. The first to third upper electrodes UE1, UE2, and UE3 may be patterned by the tip defined in the conductive partition wall CPW.

In the disclosure, the first upper electrode UE1 may contact the inner surface of the first conductive layer CDL1 that defines the first area OP1-U1 of the first upper opening OP1-U therein.

According to the disclosure, as the first to third upper electrodes UE1, UE2, and UE3 are not provided in a form of a common layer that overlaps all of the first to third light-emitting patterns EP1, EP1, and EP3, a lateral leakage current that occurs through the common layer may not occur.

Capping patterns CP1, CP2, and CP3 may include the first capping pattern CP1 disposed on the first upper electrode UE1 inside the first upper opening OP1-U, the second capping pattern CP2 disposed on the second upper electrode UE2 inside the second upper opening OP2-U, and the third capping pattern CP3 disposed on the third upper electrode UE3 inside the third upper opening OP3-U. The first to third capping patterns CP1, CP2, and CP3 may be patterned by the tip defined in the conductive partition wall CPW. In another embodiment of the disclosure, the first to third capping patterns CP1, CP2, and CP3 may be omitted.

Although FIG. 6A shows as an embodiment in which the first capping pattern CP1 is not in contact with the inner surface of the first conductive layer CDL1 that defines the first upper opening OP1-U therein, the disclosure is not limited thereto. In an embodiment, the first capping pattern CP1 may be formed to contact the inner surface of the first conductive layer CDL1 that defines the first upper opening OP1-U therein, for example.

Referring back to FIG. 5, the dummy patterns DMP1, DMP2, and DMP3 may be disposed on the conductive partition wall CPW. The dummy patterns DMP1, DMP2, and DMP3 may include the first dummy pattern DMP1, the second dummy pattern DMP2, and the third dummy pattern DMP3.

The first dummy pattern DMP1 may be disposed on the top surface US_CPW of the conductive partition wall CPW. The first dummy pattern DMP1 may cover at least a portion of the inner surface of the second conductive layer CDL2 that defines the first upper opening OP1-U therein. The first dummy pattern DMP1 may be at least partially covered by the first lower encapsulation inorganic film LIL1.

As shown in FIG. 6A, the first dummy pattern DMP1 may include the first organic layer L1, the first conductive layer L2, and the first capping layer L3. The first organic layer L1 may be formed via the same process as, have the same structure as, and may include or consist of the same material as that of the first light-emitting pattern EP1. The first organic layer L1 may be spaced apart from the first to third light-emitting patterns EP1, EP2, and EP3. The first organic layer L1 may correspond to a residue separated from the first light-emitting pattern EP1 by the conductive partition wall CPW when the first light-emitting pattern EP1 is commonly formed. The first conductive layer L2 may be disposed on the first organic layer L1. The first conductive layer L2 may be formed via the same process as, have the same structure as, and may include or consist of the same material as that of the first upper electrode UE1. The first conductive layer L2 may be spaced apart from the first to third upper electrodes UE1, UE2, and UE3. The first conductive layer L2 may correspond to a residue separated from the first upper electrode UE1 by the conductive partition wall CPW when the first upper electrode UE1 is commonly formed. The first capping layer L3 may be disposed on the first conductive layer L2. The first capping layer L3 may be formed via the same process as, have the same structure as, and may include or consist of the same material as that of the first capping pattern CP1. The first capping layer L3 may be spaced apart from the first to third capping patterns CP1, CP2, and CP3. The first capping layer L3 may correspond to a residue separated from the first capping pattern CP1 by the conductive partition wall CPW when the first capping pattern CP1 is commonly formed.

The second dummy pattern DMP2 may include a first dummy portion DPP1 and a second dummy portion DPP2.

A portion of the first dummy portion DPP1 may be disposed on the first dummy pattern DMP1 above the top surface of the conductive partition wall CPW. The second dummy portion DPP2 may be spaced apart from the first dummy portion DPP1 and may be disposed on the first dummy pattern DMP1 above the top surface of the conductive partition wall CPW. Each of the first and second dummy portions DPP1 and DPP2 of the second dummy pattern DMP2 may include a second organic layer, a second conductive layer, and a second capping layer. The descriptions of the first organic layer L1, the first conductive layer L2, and the first capping layer L3 may be similarly applied to the second organic layer, the second conductive layer, and the second capping layer. The second organic layer may include or consist of the same material as that of the second light-emitting pattern EP2 and may be spaced apart from the first to third light-emitting patterns EP1, EP2, and EP3. The second conductive layer may be disposed on the second organic layer. The second conductive layer may include or consist of the same material as that of the second upper electrode UE2 and may be spaced apart from the first to third upper electrodes UE1, UE2, and UE3. The second capping layer may be disposed on the second conductive layer. The second capping layer may include or consist of the same material as that of the second capping pattern CP2 and may be spaced apart from the first to third capping patterns CP1, CP2, and CP3.

A portion of the third dummy pattern DMP3 may be disposed on a side surface of the first dummy pattern DMP1, a side surface of the second dummy portion DPP2, and a side surface of the second conductive layer CDL2. A portion of the third dummy pattern DMP3 may be disposed on the first dummy pattern DMP1 and second dummy pattern DMP2 above the top surface of the conductive partition wall CPW.

The third dummy pattern DMP3 may include a third organic layer including or consisting of the same material as that of the third light-emitting pattern EP3, a third conductive layer including or consisting of the same material as that of the third upper electrode UE3 and disposed on the third organic layer, and a third capping layer including or consisting of the same material as that of the third capping pattern CP3 and disposed on the third conductive layer. The descriptions of the first organic layer L1, the first conductive layer L2, and the first capping layer L3 may be similarly applied to the third organic layer, the third conductive layer, and the third capping layer.

The dummy inorganic film LIL2-D may be disposed between the second dummy portion DPP2 and the third dummy pattern DMP3. The dummy inorganic film LIL2-D may be disposed on the first lower encapsulation inorganic film LIL1. The dummy inorganic film LIL2-D may overlap the first lower encapsulation inorganic film LIL1.

The thin film encapsulation layer TFE may be disposed on the light-emitting element layer DP-OLED. The thin film encapsulation layer TFE may include the first lower encapsulation inorganic film LIL1, a second lower encapsulation inorganic film LIL2, a third lower encapsulation inorganic film LIL3, an encapsulation organic film OL, and an upper encapsulation inorganic film UIL.

The first lower encapsulation inorganic film LIL1 may be formed on the conductive partition wall CPW and the first upper electrode UE1, and may be disposed inside the first upper opening OP1-U. Specifically, the first lower encapsulation inorganic film LIL1 may cover the first dummy pattern DMP1 and the first upper electrode UE1 (or the first capping pattern CP1). Additionally, the first lower encapsulation inorganic film LIL1 may contact the inner surface of the first conductive layer CDL1 that defines the first upper opening OP1-U therein.

The second lower encapsulation inorganic film LIL2 may be disposed on the second upper electrode UE2 and the first dummy portion DPP1 of the second dummy pattern DMP2, and may be disposed inside the second upper opening OP2-U. Specifically, the second lower encapsulation inorganic film LIL2 may cover the second upper electrode UE2 (or the second capping pattern CP2). Additionally, the second lower encapsulation inorganic film LIL2 may contact the inner surface of the first conductive layer CDL1 that defines the second upper opening OP2-U therein. The second lower encapsulation inorganic film LIL2 may overlap an inner surface of the first lower encapsulation inorganic film LIL1 that defines a first encapsulation opening OP1-IL. A portion of the second lower encapsulation inorganic film LIL2 may be disposed on the first lower encapsulation inorganic film LIL1 above the top surface of the conductive partition wall CPW.

The third lower encapsulation inorganic film LIL3 may be disposed on the third upper electrode UE3 and the third dummy pattern DMP3, and may be disposed inside the third upper opening OP3-U. Specifically, the third lower encapsulation inorganic film LIL3 may cover the third upper electrode UE3 (or the third capping pattern CP3).

In an embodiment, each of the first lower encapsulation inorganic film LIL1, the second lower encapsulation inorganic film LIL2, and the third lower encapsulation inorganic film LIL3 may also contact a bottom surface of the second conductive layer CDL2 exposed from the first conductive layer CDL1.

The first to third lower encapsulation inorganic films LIL1, LIL2, and LIL3 and the upper encapsulation inorganic film UIL may protect the light-emitting element layer DP-OLED from moisture/oxygen, and the encapsulation organic film OL may protect the light-emitting element layer DP-OLED from the foreign substances such as dust particles.

Referring to FIG. 6B, the conductive partition wall CPW in an embodiment may include the first conductive layer CDL1, the second conductive layer CDL2, and a third conductive layer CDL3. The third conductive layer CDL3 may be disposed beneath the first conductive layer CDL1. The third conductive layer CDL3 may have third conductivity lower than the first conductivity and a third thickness smaller than the first thickness.

The third conductive layer CDL3 may include or consist of a conductive material. In an embodiment, the third conductive layer CDL3 may include or consist of the same material as that of the second conductive layer CDL2, and the first conductive layer CDL1 may include or consist of a material different from that of the second and third conductive layers CDL2 and CDL3. In an embodiment, the second and third conductive layers CDL2 and CDL3 may include or consist of titanium (Ti), and the first conductive layer CDL1 may include or consist of aluminum (Al). The third conductive layer CDL3 may include or consist of a material that has greater adhesion to the insulating layer ISL than an adhesion of the second conductive layer CDL2 to the insulating layer ISL, for example. Accordingly, the conductive partition wall CPW may be adhered to the insulating film ISL with great adhesion, and process reliability may be improved.

An etch rate of the third conductive layer CDL3 may be smaller than the etch rate of the first conductive layer CDL1. In other words, the first conductive layer CDL1 may include or consist of a material with higher etch selectivity than that of the third conductive layer CDL3.

Each of FIGS. 7A to 9 is a cross-sectional view showing an embodiment of one operation of a display panel manufacturing method according to the disclosure. FIGS. 7A to 9 show portions corresponding to FIG. 6A.

The contents of the same components described above with reference to FIGS. 5 to 6B may be equally applied to FIGS. 7A to 9.

The display panel manufacturing method according to the disclosure may include preparing the base layer BL, forming the circuit element layer DP-CL on the base layer BL, and forming the light-emitting element layer DP-OLED on the circuit element layer DP-CL, and forming the encapsulation layer TFE on the light-emitting element layer DP-OLED.

FIGS. 7A and 7B show the preparing of the base layer BL and the forming of the circuit element layer DP-CL on the base layer BL.

In the preparing of the base layer BL, the contents described above regarding the base layer BL in FIGS. 5 to 6B may be applied.

The forming of the circuit element layer DP-CL may include preparing the first circuit layer DP-CL1, forming the power electrode PL on the first circuit layer DP-CL1, and forming the second circuit layer 60 defining an opening therein to expose the power electrode PL on the first circuit layer DP-CL1.

The first circuit layer DP-CL1 may be formed across the base layer BL, and may include the buffer layer, the first to fifth insulating layers, and the plurality of components disposed between the buffer layer and the fifth insulating layer described above in FIG. 6A. In FIGS. 7A and 7B, the above components are collectively shown as the first circuit layer DP-CL1 for convenience.

Referring to FIG. 7A, the second connection electrode CNE2 and the power electrode PL may be formed on the first circuit layer DP-CL1 to be spaced apart from each other. The power electrode PL may include the first layer PL1, the second layer PL2, and the third layer PL3. However, a stacked structure of the power electrode PL is not limited thereto. In addition, the contents described above in FIGS. 5 to 6B may be equally applied to the power electrode PL.

Referring to FIG. 7B, the second circuit layer 60 may be formed on the first circuit layer DP-CL1. The second circuit layer 60 may define an opening OP-60 therein. The opening OP-60 of the second circuit layer 60 may expose the power electrode PL. The first circuit layer DP-CL1 may include the connection contact hole CNT-3. The connection contact hole CNT-3 may expose at least a portion of the second connection electrode CNE2.

FIGS. 8A to 8D show the forming of the light-emitting element layer DP-OLED on the circuit element layer DP-CL.

The forming of the light-emitting element layer DP-OLED may include forming the lower electrode LE1 and the auxiliary electrode AXE-R, forming the pixel defining film ISL that covers a portion of the lower electrode LE1, forming the conductive partition wall CPW on the pixel defining film ISL, forming the light-emitting pattern EP1 on the lower electrode LE1, and forming the upper electrode UE1 on the light-emitting pattern EP1.

Referring to FIG. 8A, the lower electrode LE1 may be formed on the second circuit layer 60 while filling the connection contact hole CNT-3, and may contact and electrically connected to the second connection electrode CNE2. The auxiliary electrode AXE-R may include or consist of the same material as that of the lower electrode LE1 and may be formed in the same process operation.

The auxiliary electrode AXE-R may be spaced apart from the lower electrode LE1. The auxiliary electrode AXE-R may be formed in the opening OP-60 of the second circuit layer 60. In FIG. 8A, the auxiliary electrode AXE-R is shown to cover the entirety of the opening OP-60, but the disclosure is not limited thereto. In an embodiment, the auxiliary electrode AXE-R may be formed without covering the portion of the first circuit layer DP-CL1 exposed by the opening OP-60, for example.

The auxiliary electrode AXE-R may be formed directly on the power electrode PL. Specifically, the auxiliary electrode AXE-R may be formed to cover at least a portion of the side surface of the power electrode PL. In the forming of the lower electrode LE1 and the auxiliary electrode AXE-R, a first dummy L0 including or consisting of the same material as that of the lower electrode LE1 and the auxiliary electrode AXE-R may be formed on the power electrode PL. The power electrode PL and the auxiliary electrode AXE-R may be electrically connected to each other.

Referring to FIG. 8B, the first sacrificial pattern SP1 and the pixel defining film ISL may be formed on the lower electrode LE1. The pixel defining film ISL may define the pixel opening OP1-E (refer to FIG. 9).

Referring to FIG. 8C, the conductive partition wall CPW may be formed on the pixel defining film ISL. The conductive partition wall CPW may include the first conductive layer CDL1 and the second conductive layer CDL2.

Referring to FIG. 8D, the light-emitting pattern EP1, the upper electrode UE1, and the first capping pattern CP1 may be formed on the lower electrode LE1, the auxiliary electrode AXE-R, and the conductive partition wall CPW. The first capping pattern CP1 may be omitted. The light-emitting pattern EP1, the upper electrode UE1, and the first capping pattern CP1 formed on the auxiliary electrode AXE-R may be also referred to as the first-first dummy pattern DMP1-1. The light-emitting pattern EP1, the upper electrode UE1, and the first capping pattern CP1 formed on the conductive partition wall CPW may be also referred to as the first dummy pattern DMP1.

The upper electrode UE1 may be formed continuously from a top of the first lower electrode LE1 to a top of the auxiliary electrode AXE-R. The upper electrode UE1 may also be formed on a portion of the auxiliary electrode AXE-R formed on the side surface of the power electrode PL, and may be electrically connected to the power electrode PL via the auxiliary electrode AXE-R.

Referring to FIG. 9, the forming of the encapsulation layer TFE may include forming the first lower encapsulation inorganic film LIL1, forming the encapsulation organic film OL, and forming the upper encapsulation inorganic film UIL.

The first lower encapsulation inorganic film LIL1 may be formed to cover the conductive partition wall CPW, the capping pattern CP1, and the first and first-first dummy patterns DMP1 and DMP1-1. The encapsulation organic film OL may be formed for a purpose of flattening by covering a step caused by the circuit element layer DP-CL and the light-emitting element layer DP-OLED. The upper encapsulation inorganic film UIL may be formed on the encapsulation organic film OL.

According to the above, the reliability of the display panel according to the disclosure may be improved as the contact stability of the upper electrode is improved.

Additionally, the display panel manufacturing method according to the disclosure may simplify the process.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display panel comprising:
a base layer;
a circuit element layer disposed on the base layer, the circuit element layer including:
a power electrode; and
an auxiliary electrode disposed on a side surface of the power electrode; and
a light-emitting element layer disposed on the circuit element layer, the light-emitting element layer including:
a pixel defining film which defines a pixel opening;
a conductive partition wall disposed on the pixel defining film; the conductive partition wall including:
a first conductive layer disposed on the pixel defining film, and a second conductive layer disposed on the first conductive layer, and a side surface of the second conductive layer more protrudes than a side surface of the first conductive layer;
a lower electrode disposed in the pixel opening;
a light-emitting pattern disposed on the lower electrode; and
an upper electrode disposed on the light-emitting pattern,
wherein the upper electrode is electrically connected to the power electrode via the auxiliary electrode.

2. The display panel of claim 1, wherein the circuit element layer further includes a first circuit layer disposed on the base layer, and a second circuit layer defining an opening and disposed on the first circuit layer, and
wherein the power electrode is disposed in the opening of the second circuit layer.

3. The display panel of claim 2, wherein the opening of the second circuit layer is spaced apart from the lower electrode in a plan view.

4. The display panel of claim 2, wherein the auxiliary electrode is disposed directly on the side surface of the power electrode in a plan view.

5. The display panel of claim 2, wherein the pixel defining film is disposed on the second circuit layer.

6. The display panel of claim 1, wherein the auxiliary electrode includes or consists of a same material as a material of the lower electrode.

7. The display panel of claim 1, wherein the auxiliary electrode is spaced apart from the lower electrode in a plan view and electrically insulated from the lower electrode.

8. The display panel of claim 1, wherein the circuit element layer further includes a transistor, and
wherein the lower electrode is electrically connected to the transistor.

9. The display panel of claim 1, wherein the conductive partition wall further includes a third conductive layer disposed between the first conductive layer and the pixel defining film, and
wherein a side surface of the third conductive layer more protrudes than the side surface of the second conductive layer.

10. The display panel of claim 1, wherein the power electrode includes a first layer, a second layer disposed on the first layer, and a third layer disposed on the second layer, and
wherein a side surface of the first layer and a side surface of the third layer protrude further than a side surface of the second layer.

11. The display panel of claim 1, wherein the lower electrode and the auxiliary electrode include ITO.

12. The display panel of claim 1, wherein the power electrode includes Al.

13. A method for manufacturing a display panel, the method comprising:
preparing a base layer;
forming a circuit element layer on the base layer, the forming the circuit element layer including:
forming a power electrode on a first circuit layer; and
forming a second circuit layer defining an opening which exposes the power electrode on the first circuit layer,
forming a light-emitting element layer on the circuit element layer, the forming the light-emitting element layer including:
forming a lower electrode and an auxiliary electrode;
forming a pixel defining film which covers a portion of the lower electrode;
forming a conductive partition wall on the pixel defining film, the forming the conductive partition wall including:
forming a first conductive layer; and
forming a second conductive layer on the first conductive layer;
forming a light-emitting pattern on the lower electrode; and
forming an upper electrode on the light-emitting pattern,
wherein a side surface of the first conductive layer is formed to protrude further than a side surface of the second conductive layer.

14. The method of claim 13, wherein the lower electrode and the auxiliary electrode include a same material and are formed in a same process step.

15. The method of claim 13, wherein the lower electrode and the auxiliary electrode are spaced apart from each other in a plan view.

16. The method of claim 13, wherein the auxiliary electrode is formed at least on a side surface of the power electrode.

17. The method of claim 13, wherein the upper electrode is formed to overlap the lower electrode and the auxiliary electrode in a plan view.

18. The method of claim 13, wherein the upper electrode is formed to contact a portion of the auxiliary electrode disposed on a side surface of the power electrode.

19. The method of claim 13, wherein an etch rate of the first conductive layer is greater than an etch rate of the second conductive layer.

20. The method of claim 13, wherein the forming the conductive partition wall further includes forming a third conductive layer on the second conductive layer, and
wherein a side surface of the third conductive layer is formed to protrude further than the side surface of the second conductive layer.
